(19) United States
(12) Patent Application Publication
(10) Pub. No.: US 2013/0140570 A1
(43) Pub. Date: Jun. 6, 2013

(54) THIN FILM TRANSISTOR ARRAY PANEL

(71) Applicants: Hoon KANG, Suwon-si (KR); Jae-Sung KIM, Suwon-Si (KR); Jin-Young CHOI, Incheon (KR); Sang Gab KIM, Seoul (KR); Koichi Sugitani, Hwaseong-si (KR)

(72) Inventors: Hoon KANG, Suwon-si (KR); Jae-Sung KIM, Suwon-Si (KR); Jin-Young CHOI, Incheon (KR); Sang Gab KIM, Seoul (KR); Koichi Sugitani, Hwaseong-si (KR)

(73) Assignee: SAMSUNG ELECTRONICS CO., LTD., Suwon-si (KR)

(21) Appl. No.: 13/440,435

(22) Filed: Apr. 5, 2012

(30) Foreign Application Priority Data
Dec. 1, 2011 (KR) 10-2011-0127718

(51) Int. Cl. H01L 29/786

(52) U.S. Cl. 257/59; 257/E29.273

(57) ABSTRACT

A thin film transistor array panel includes an insulation substrate; a gate line on the insulation substrate; a gate insulating layer on the gate line; a data line on the gate insulating layer; a first insulating layer on the data line and including a first contact hole which exposes a portion of the data line; a first connection assistant member in the first contact hole; and further including a first field generating electrode on the first insulating layer. The first field generating electrode is in connection with the exposed portion of the data line through the first connection assistant member.

This application claims priority to Korean Patent Application No. 10-2011-0127718 filed on Dec. 1, 2011, and all the benefits accruing therefrom under 35 U.S.C. §119, the entire contents of which are incorporated herein by reference.

### BACKGROUND OF THE INVENTION

(a) Field of the Invention

The invention relates to a thin film transistor array panel.

(b) Description of the Related Art

A liquid crystal display, which is one of the most common types of flat panel displays used, includes two sheets of display panels with field generating electrodes such as a pixel electrode and a common electrode, and a liquid crystal layer interposed therebetween. The liquid crystal display generates electric fields in the liquid crystal layer by applying voltage to the field generating electrodes, and determines the direction of liquid crystal molecules of the liquid crystal layer by the generated electric field, thus controlling polarization of incident light so as to display images. In the liquid crystal display, the pixel electrode and the common electrode which generate an electric field in the liquid crystal layer may be on a thin film transistor array panel.

When a pad part for connecting a driving circuit for applying gate voltage and data voltage to the field generating electrode of the liquid crystal display is formed, and a passivation layer is thick, a depth of a contact hole for exposing the pad part becomes larger, such that a connection member for connecting the pad part and the driving circuit to each other may be disconnected.

Particularly, when two field generating electrodes are on the thin film transistor array panel, an organic insulating layer is used as the passivation layer, such that a depth of the contact hole for exposing the pad part increases even more.

Further, a thin film transistor of the liquid crystal display includes a gate electrode connected to a gate line, a source electrode connected to a data line, a drain electrode connected to a pixel electrode, a semiconductor layer facing the gate electrode with an insulating layer therebetween, and the like. The thin film transistor transfers a data signal from the data line to the pixel electrode according to a scanning signal from the gate line. In this case, the semiconductor layer of the thin film transistor may include polysilicon (polycrystalline silicon) or amorphous silicon.

Since polysilicon has large electron mobility as compared with amorphous silicon, high-speed driving may be performed by using a polysilicon thin film transistor. However, in the case of the thin film transistor including the polysilicon semiconductor layer, the depth of the contact hole of the insulating layer which exposes a source region and a drain region on a polysilicon layer becomes larger, such that the source electrode and the drain electrode in the contact hole may be disconnected.

Further, when the passivation layer on the thin film transistor is thick, the depth of the contact hole exposing the drain electrode of the thin film transistor becomes larger and as a result, the pixel electrode connected with the drain electrode through the contact hole may be disconnected in the contact hole.

### BRIEF SUMMARY OF THE INVENTION

The invention provides a thin film transistor array panel having advantages of firmly connecting a portion exposed by a contact hole and a conductive layer formed thereon regardless of a depth of the contact hole and the like, even in the case where an insulating layer with the contact hole is thick.

An exemplary embodiment of the invention provides a thin film transistor array panel including: an insulation substrate; a gate line on the insulation substrate; a gate insulating layer on the gate line; a data line on the gate insulating layer; a first insulating layer on the data line and including a first contact hole; a first connection assistant member in the first contact hole; and a first field generating electrode on the first insulating layer. The first field generating electrode is in connection with the exposed portion of the data line through the first connection assistant member.

The gate line may include a gate pad, the data line may include a data pad, a second contact hole may be in the first insulating layer and the gate insulating layer, and exposes the gate pad, a third contact hole may be in the first insulating layer and exposing the data pad, a second connection assistant member may be in the second contact hole, and a third connection assistant member may be in the third contact hole.

The thin film transistor array panel may further include a first connecting member overlapping the second contact hole and electrically connected to the gate pad through the second connection assistant member; and a second connecting member overlapping the third contact hole and electrically connected to the data pad through the third connection assistant member.

The thin film transistor array panel may further include a second insulating layer on the first field generating electrode and a second field generating electrode on the second insulating layer. The first connecting member and the second connecting member may be on the same layer one of the first field generating electrode and the second field generating electrode.

One of the first connection assistant member, the second connection assistant member and the third connection assistant member may include one of molybdenum (Mo), copper (Cu), aluminum (Al), nickel (Ni), platinum (Pt), gold (Au), silver (Ag) and chromium (Cr).

One of the first connection assistant member, the second connection assistant member and the third connection assistant member may be formed by an inkjet printing method using a laser.

One of the first connection assistant member, the second connection assistant member and the third connection assistant member may be formed by a paste method using a needle.

One of the first connection assistant member, the second connection assistant member and the third connection assistant member may have a form formed by collecting small metallic particles.

One of the first connection assistant member, the second connection assistant member and the third connection assistant member may be formed by an electroless plating method.

One of the first connection assistant member, the second connection assistant member and the third connection assistant member may have a multi-layered structure including a lower seed layer and an upper plating layer.

Another exemplary embodiment of the invention provides a thin film transistor array panel including: an insulation substrate; a semiconductor on the insulation substrate and including a channel region, a source region and a drain region; a gate insulating layer on the semiconductor; a gate line on the gate insulating layer and including a gate electrode; a first insulating layer on the gate line and the gate insulating layer; a data line and a drain electrode on the first insulating layer, the data line including a source electrode; a second insulating layer on the data line and the drain electrode; and a first field generating electrode on the second insulating layer. A fourth contact hole is in the first insulating layer and the gate insulating layer and exposes the source electrode, and a fifth contact hole is in the first insulating layer and the gate insulating layer and exposes the drain electrode, a fourth connection assistant member is in the fourth contact hole, and a fifth connection assistant member is in the fifth contact hole.

The fourth connection assistant member and the fifth connection assistant member may include one of molybdenum (Mo), copper (Cu), aluminum (Al), nickel (Ni), platinum (Pt), gold (Au), silver (Ag) and chromium (Cr).

The fourth connection assistant member and the fifth connection assistant member may be formed by an inkjet printing method using a laser.

The fourth connection assistant member and the fifth connection assistant member may be formed by a paste method using a needle.

The fourth connection assistant member and the fifth connection assistant member may have forms formed by collecting small metallic particles.

The fourth connection assistant member and the fifth connection assistant member may be formed by an electroless plating method.

The fourth connection assistant member and the fifth connection assistant member may have a multi-layered structure including a lower seed layer and an upper plating layer.

The source electrode may be electrically connected to the source region through the fourth connection assistant member in the fourth contact hole.

The drain electrode may be electrically connected to the drain region through the fifth connection assistant member in the fifth contact hole.

According to the exemplary embodiments of the invention, a portion of the contact hole of the thin film transistor array panel is filled by the connection assistant member. Therefore, even though the depth of the contact hole becomes larger and a taper angle of the contact hole increases, the connection assistant member is between the portion exposed by the contact hole and the conductive layer thereon, and the portion exposed by the contact hole and the conductive layer thereon are connected with each other through the connection assistant member, such that the portion exposed by the contact hole and the conductive layer thereon may be firmly connected to each other.

### BRIEF DESCRIPTION OF THE DRAWINGS

The above and other features of this disclosure will become more apparent by describing in further detail exemplary embodiments thereof with reference to the accompanying drawings, in which:

FIG. 1 is a plan view of an exemplary embodiment of a thin film transistor array panel according to the invention.

FIG. 2 is a cross-sectional view of the thin film transistor array panel of FIG. 1 taken along line II-II.

FIG. 3 is a cross-sectional view of the thin film transistor array panel of FIG. 1 taken along line III-III.

FIG. 4 is a cross-sectional view of the thin film transistor array panel of FIG. 1 taken along line IV-IV.

FIG. 5 is a cross-sectional view of the thin film transistor array panel of FIG. 1 taken along line V-V.

FIG. 6 is a plan view of another exemplary embodiment of a thin film transistor array panel according to the invention.

FIG. 7 is a cross-sectional view of the thin film transistor array panel of FIG. 6 taken along line VII-VII.

FIG. 8 is a cross-sectional view of the thin film transistor array panel of FIG. 6 taken along line VIII-VIII.

FIG. 9 is a cross-sectional view of the thin film transistor array panel of FIG. 6 taken along line IX-IX.

FIG. 10 is a cross-sectional view of the thin film transistor array panel of FIG. 6 taken along line X-X.

FIG. 11 is a plan view of an exemplary embodiment a liquid crystal display including a thin film transistor array panel according to the invention.

FIG. 12 is a cross-sectional view of the liquid crystal display of FIG. 11 taken along line XII-XII.

FIG. 13 is a plan view of another exemplary embodiment of a liquid crystal display including a thin film transistor array panel according to the invention.

FIG. 14 is a cross-sectional view of the liquid crystal display of FIG. 13 taken along line XIV-XIV.

FIG. 15 is a plan view of yet another exemplary embodiment of a thin film transistor array panel according to y the invention.

FIG. 16 is a cross-sectional view of the thin film transistor array panel of FIG. 15 taken along line XVI-XVI.

FIG. 17 is a cross-sectional view of the thin film transistor array panel of FIG. 15 taken along line XVII-XVII.

FIGS. 18(a), 18(b) and 18(c) are photographs illustrating an exemplary embodiment of forming a metal layer using a droplet or paste type metallic material, where FIG. 18(a) is a cross-sectional photograph, FIG. 18(b) is a photograph of an upper surface, and FIG. 18(c) is an enlarged photograph of the cross section.

### DETAILED DESCRIPTION OF THE INVENTION

The invention will be described more fully hereinafter with reference to the accompanying drawings, in which exemplary embodiments of the invention are shown. As those skilled in the art would realize, the described embodiments may be modified in various different ways, all without departing from the spirit or scope of the invention.

In the drawings, the thickness of layers, films, panels, regions, etc., are exaggerated for clarity. Like reference numerals designate like elements throughout the specification. It will be understood that when an element such as a layer, film, region, or substrate is referred to as being “on” or “connected to” another element, it can be directly on or connected to the other element or intervening elements may also be present. In contrast, when an element is referred to as being “directly on” or “directly connected to” another element, there are no intervening elements present.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the invention.

Spatially relative terms, such as “below,” “lower,” “above,” “upper” and the like, may be used herein for ease of description to describe the relationship of one element or feature to another element(s) or feature(s) as illustrated in the figures. It will be understood that the spatially relative terms are intended to encompass different orientations of the device in use or operation, in addition to the orientation depicted in the figures. For example, if the device in the figures is turned over, elements described as “below” relative to other elements or features would then be oriented “above” relative to the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the invention as used herein.

Hereinafter, the invention will be described in detail with reference to the accompanying drawings.

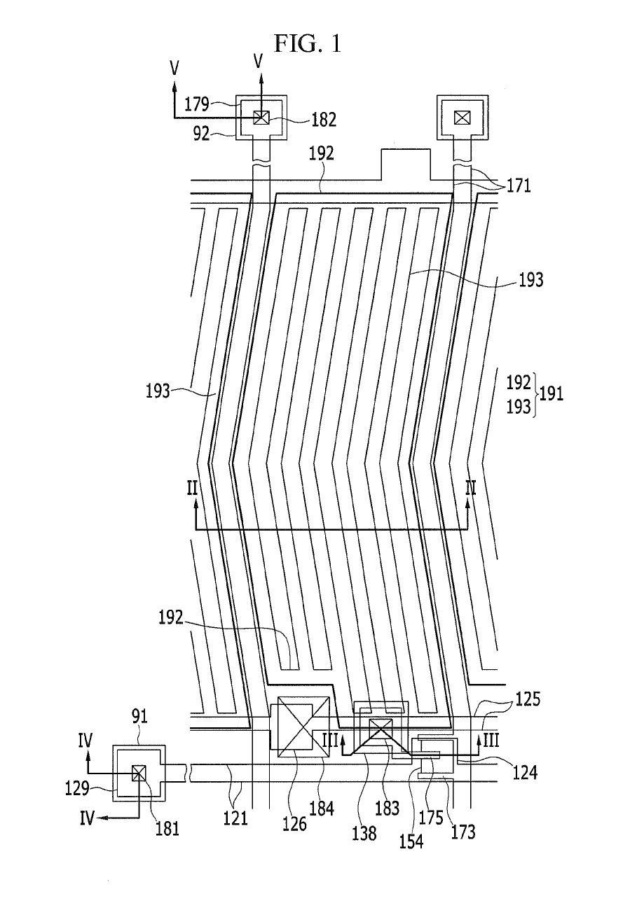

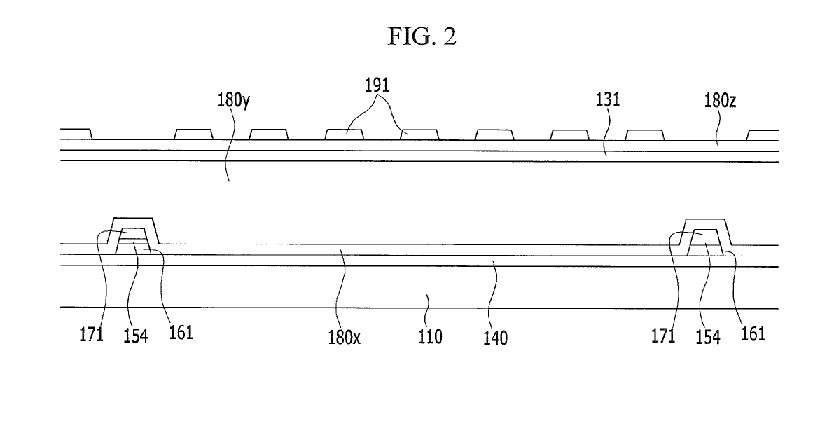

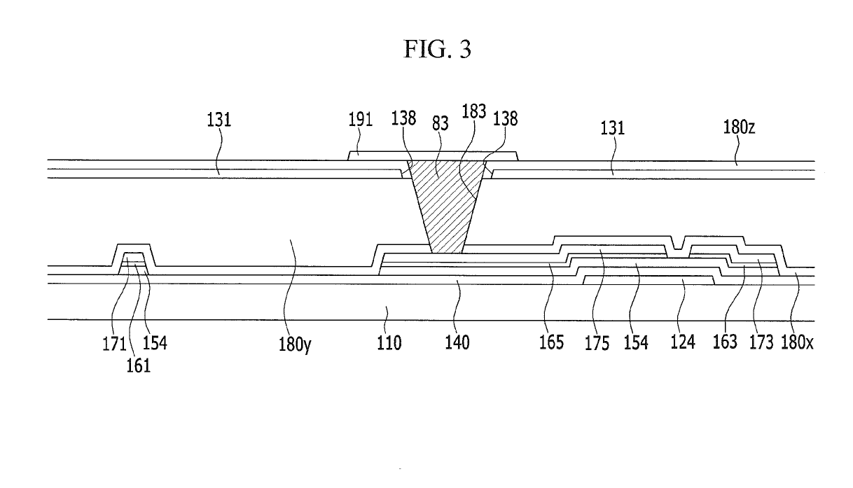

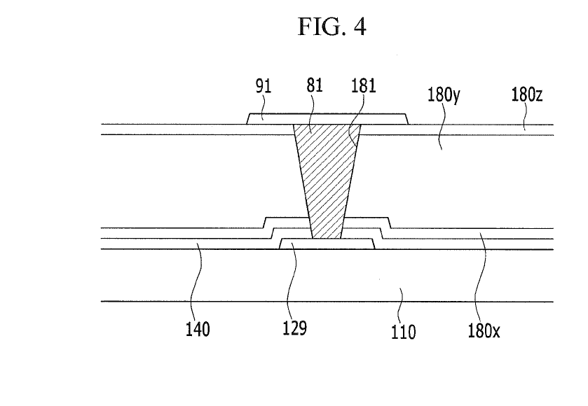

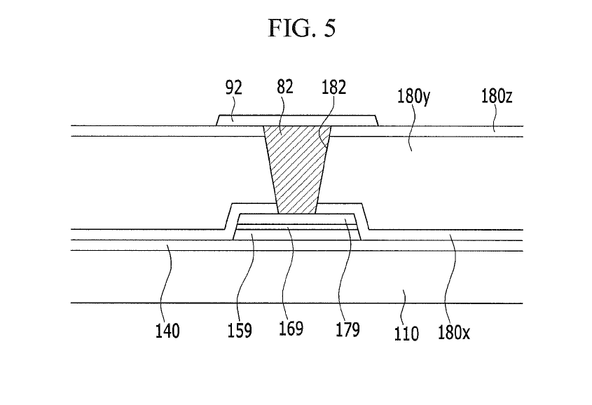

First, an exemplary embodiment of a thin film transistor array panel according to the invention will be described with reference to FIGS. 1 to 5. FIG. 1 is a plan view of an exemplary embodiment of a thin film transistor array panel according to the invention, FIG. 2 is a cross-sectional view of the thin film transistor array panel of FIG. 1 taken along line II-II, FIG. 3 is a cross-sectional view of the thin film transistor array panel of FIG. 1 taken along line III-III, FIG. 4 is a cross-sectional view of the thin film transistor array panel of FIG. 1 taken along line IV-IV, and FIG. 5 is a cross-sectional view of the thin film transistor array panel of FIG. 1 taken along line V-V.

Referring to FIGS. 1 to 5, a gate conductor including a plurality of gate lines 121 and a plurality of common voltage lines 125 are on an insulation substrate 110.

Each of the gate lines 121 includes a plurality of gate electrodes 124 protruding downwards in a vertical direction in the plan view, and a gate pad 129 having a wide area for connection with another layer or an external driving circuit. A gate driving circuit (not shown) generating a gate signal may be mounted on a flexible printed circuit film (not shown) which is attached onto the insulation substrate 110, or may be directly mounted on the insulation substrate 110.

The common voltage lines 125 transfer predetermined voltage such as common voltage Vcom and the like, and may have a longitudinal axis that substantially extends in a horizontal direction in the plan view and be substantially parallel to a longitudinal axis of the gate lines 121. Each of the common voltage lines 125 may include a plurality of extensions 126.

The gate conductors 121 and 125 may be a single layer and/or be a multilayer including two or more conductive layers.

A gate insulating layer 140 is on the gate conductors 121 and 125. The gate insulating layer 140 may include an inorganic insulator such as silicon nitride (SiNx) or silicon oxide (SiOx).

A plurality of semiconductors 154 are on the gate insulating layer 140. Ohmic contacts 161, 163 and 165 are disposed on the semiconductor 154 and may be omitted in an alternative embodiment.

A data conductor including a plurality of data lines 171 and a plurality of drain electrodes 175 is on the ohmic contacts.

The data lines 171 transfer data signals and mainly extend in a vertical direction of the plan view to cross the gate lines 121 and the common voltage lines 125. Each of the data lines 171 includes a plurality of source electrodes 173 extending toward the gate electrodes 124, and a data pad 179 having a wide area for connection with another layer or an external driving circuit. A data driving circuit (not shown) generating a data signal may be mounted on a flexible printed circuit film (not shown) attached to the insulation substrate 110, or may be directly mounted on the insulation substrate 110.

The drain electrode 175 includes a rod-shaped first end portion facing the source electrode 173 with respect to the gate electrode 124, and a second end portion opposing the first end portion and having a wide area in the plan view.

The data conductors 171 and 175 may be a single layer and/or be a multilayer including two or more conductive layers.

A pad part semiconductor 159 and a pad part contact assistant member 169 are disposed below the data pad 179.

The gate electrode 124, the source electrode 173 and the drain electrode 175 form a thin film transistor (“TFT”) which is a switching element, together with the semiconductor 154. The semiconductor 154 may substantially the same planar profile as the data conductors 171 and 175 except for a channel portion of the TFT.

A first passivation layer 180x is disposed on the data line 171, the drain electrode 175 and the exposed semiconductor 154, and may include an organic insulating material, an inorganic insulating material or the like.

A second passivation layer 180y is disposed directly on the first passivation layer 180x. The second passivation layer 180y includes an organic material and covers the data lines 171. An upper surface of the second passivation layer 180y may be substantially flat.

Although not shown, in the case of an alternative embodiment of the thin film transistor array panel according to the invention, the second passivation layer 180y may be a color filter and in this case, the thin film transistor array panel may further include a layer disposed on the second passivation layer 180y. In one exemplary embodiment, for example, the thin film transistor array panel may further include a capping layer disposed on the color filter to reduce or effectively prevent flow a pigment of the color filter into the liquid crystal layer. The capping layer may include an insulating material such as silicon nitride (SiNx).

A common electrode 131 is on the second passivation layer 180y. The common electrode 131 may include a transparent conductive material such as indium tin oxide (“ITO”), indium zinc oxide (“IZO”), or the like. The common electrode 131 is electrically connected with the common voltage line 125 through contact hole 184 to receive predetermined voltage such as common voltage Vcom and the like from the common voltage line 125. In the exemplary embodiment, the common electrode 131 may be substantially planar such as a plate on an entire surface of the insulation substrate 110. The common electrode 131 has openings 138 exposing contact holes 183 for contacting the drain electrodes 175 to pixel electrodes 191.

A third passivation layer 180z is disposed on the common electrode 131, and the pixel electrodes 191 are disposed on the third passivation layer 180z. The pixel electrode 191 may include a transparent conductive material such as ITO, IZO or the like.

A first contact hole 181 exposing the gate pad 129 is extended completely through a thickness of each of the first passivation layer 180x, the second passivation layer 180y, the third passivation layer 180z and the gate insulating layer 140. The first contact hole 181 may be a single opening, and may have a planar profile of a polygon such as a square or the like, a circle, or an ellipse.

A second contact hole 182 exposing the data pad 179 is extended completely through the thickness of the first passivation layer 180x, the second passivation layer 180y and the third passivation layer 180z. The second contact hole 182 may be a single opening, and may have a planar profile of a polygon such as a square or the like, a circle, or an ellipse.

The plurality of the third contact holes 183 partially exposing the drain electrodes 175 is extended completely through the thickness of the first passivation layer 180x, the second passivation layer 180y and the third passivation layer 180z. The fourth contact hole 184 partially exposing the common voltage lines 125 is extended completely through the thickness of the first passivation layer 180x, the second passivation layer 180y and the gate insulating layer 140.

The pixel electrode 191 is electrically connected to the drain electrode 175 through the third contact hole 183 to receive data voltage. The pixel electrodes 191 includes a plurality of branch electrodes 193 having a longitudinal axis extending substantially parallel to each other and separated from each other in a direction transverse to the longitudinal axis, and lower and upper horizontal portions 192 connecting upper and lower ends of the branch electrodes 193 to each other. The branch electrode 193 of the pixel electrode 191 may be bent along the longitudinal axis thereof, and may be parallel to a planar profile of the data line 171 in the plan view.

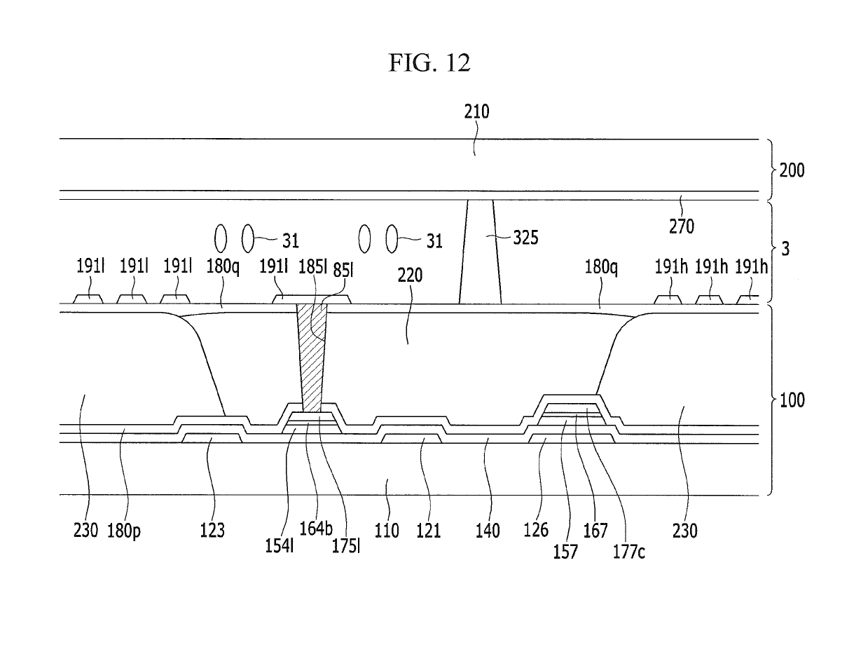

The pixel electrode 191 receiving the data voltage generates an electric field in a liquid crystal layer 3 (see FIG. 12) together with the common electrode 131 receiving the common voltage.

In the case of the exemplary embodiment of the thin film transistor array panel, the common electrode 131 is disposed below the third passivation layer 180z and the pixel electrode 191 is disposed above the third passivation layer 180z. In the case of an alternative exemplary embodiment of the thin film transistor array panel according to the invention, the pixel electrode 191 may be disposed below the third passivation layer 180z and the common electrode 131 may be disposed above the third passivation layer 180z. Further, any one of the common electrode 131 and the pixel electrode 191 may include the branch electrodes and the other electrode may have a plate shape.

That is, all characteristics of the exemplary embodiment of the thin film transistor array panel according to the invention may be applied to all the cases where both the common electrode and the pixel electrode, which are two field generating electrodes, are disposed in the thin film transistor array panel.

A first connection assistant member 81 is disposed in the first contact hole 181 exposing the gate pad 129, and a second connection assistant member 82 is disposed in the second contact hole 182 exposing the data pad 179. The first connection assistant member 81 and the second connection assistant member 82 may entirely fill the first contact hole 181 and the second contact hole 182, but may alternatively partially fill the first contact hole 181 and the second contact hole 182. That is, the first connection assistant member 81 and the second connection assistant member 82 may be in a portion of the first contact hole 181 and/or the second contact hole 182.

A first connecting member 91 is disposed overlapping the first contact hole 181 and the first connection assistant member 81, and a second connecting member 92 is disposed overlapping the second contact hole 182 and the second connection assistant member 82.

The first connecting member 91 is connected with the gate pad 129 through the first contact hole 181, and the first connection assistant member 81 is disposed between the first connecting member 91 and the gate pad 129 to electrically connect the first connecting member 91 and the gate pad 129 to each other. Further, the second connecting member 92 is connected with the data pad 179 through the second contact hole 182, and the second connection assistant member 82 is disposed between the second connecting member 92 and the data pad 179 to electrically connect the second connecting member 92 and the data pad 179 to each other.

A third connection assistant member 83 is disposed in the third contact hole 183 exposing a portion of the drain electrode 175. The third connection assistant member 83 may entirely fill the third contact hole 183, but may alternatively partially fill the third contact hole 183. That is, the third connection assistant member 83 may be in a portion of the third contact hole 183.

As described above, the pixel electrode 191 is connected with the drain electrode 175 through the third contact hole 183, and the third connection assistant member 83 is disposed between the drain electrode 175 and the pixel electrode 191 to electrically connect the drain electrode 175 and the pixel electrode 191 to each other.

The third connection assistant member 83 assists connection of the drain electrode 175 and the pixel electrode 191 by reducing or preventing disconnection of the pixel electrode 191 in the third contact hole 183, even as a depth of the third contact hole 183 taken in a vertical direction of the cross-sectional view becomes larger and a taper angle increases.

As described above, in the case of the exemplary embodiment of the thin film transistor array panel according to the invention, even though the depths of the contact holes 181 and 182 respectively exposing the gate pad 129 and the data pad 179 become larger, disconnection of the connecting members 91 and 92 may be reduced or effectively prevented through the first connection assistant member 81 and the second connection assistant member 82 partially filling the contact holes 181 and 182. Accordingly, even though the depths of the contact holes 181 and 182 become larger and the taper angle increases, it is possible to increase reliability of the connection between the gate pad 129 and the data pad 179 and the connecting members 91 and 92, respectively. Similarly, even though the depth of the contact hole 183 exposing the drain electrode 175 becomes larger or the taper angle increases, the third connection assistant member 83 partially filling the contact hole 183 assists connection of the drain electrode 175 and the pixel electrode 191 by reducing or effectively preventing disconnection of the pixel electrode 191 from the drain electrode 175 in the third contact hole 183.

The first connecting member 91 and the second connecting member 92 may be in or on the same layer as any one of the field generating electrodes. The first connecting member 91 and the second connecting member 92 may also include a lower layer on the same layer as the common electrode 131 disposed at the relatively lower portion of the field generating electrodes, and an upper layer on the same layer as the pixel electrode 191 disposed at the relatively upper portion of the field generating electrodes.

As described above, in the case of the exemplary embodiment of the thin film transistor array panel according to the invention, even though the depths of the contact holes 181 and 182 exposing the gate pad 129 and the data pad 179 become larger or the taper angle increases, disconnection of the connecting members 91 and 92 may be reduced or effectively prevented through the first connection assistant member 81 and the second connection assistant member 82 partially filling the contact holes 181 and 182. In addition, even though the depth of the contact hole 183 exposing the drain electrode 175 becomes larger or the taper angle increases, the third connection assistant member 83 partially filling the contact hole 183 assists connection of the drain electrode 175 and the pixel electrode 191 to each other by reducing or effectively preventing disconnection of the pixel electrode 191 from the drain electrode 175 in the third contact hole 183. Accordingly, even though the depths of the contact holes 181, 182 and 183 become larger, it is possible to increase reliability of the connection between the layer exposed through the contact holes 181, 182 and 183 and the layers 91, 92 and 191 formed thereon.

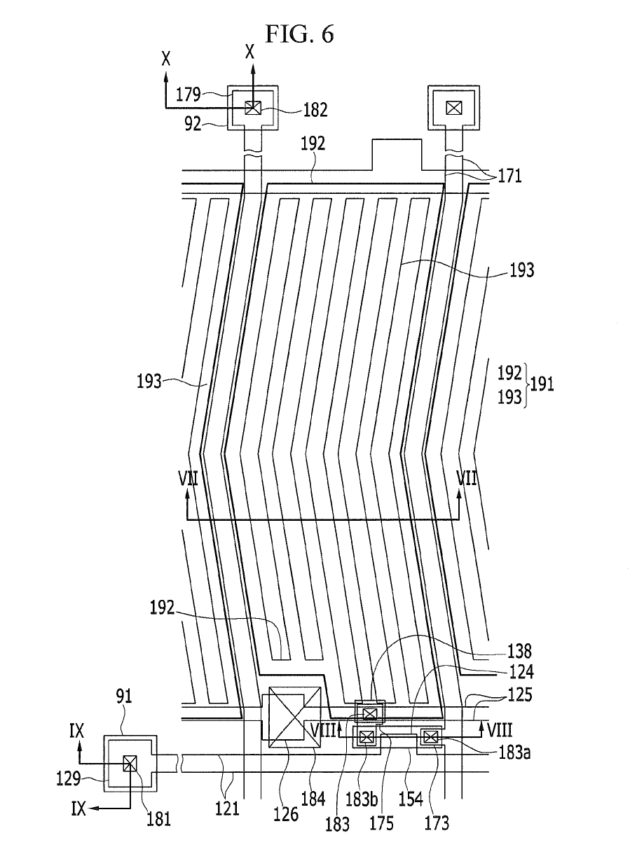

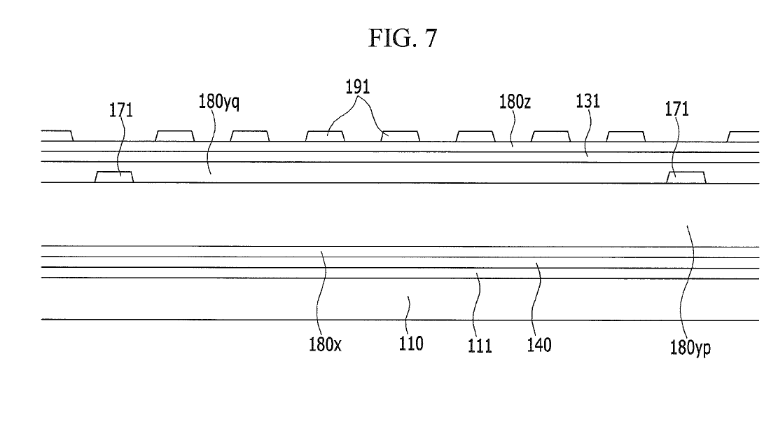

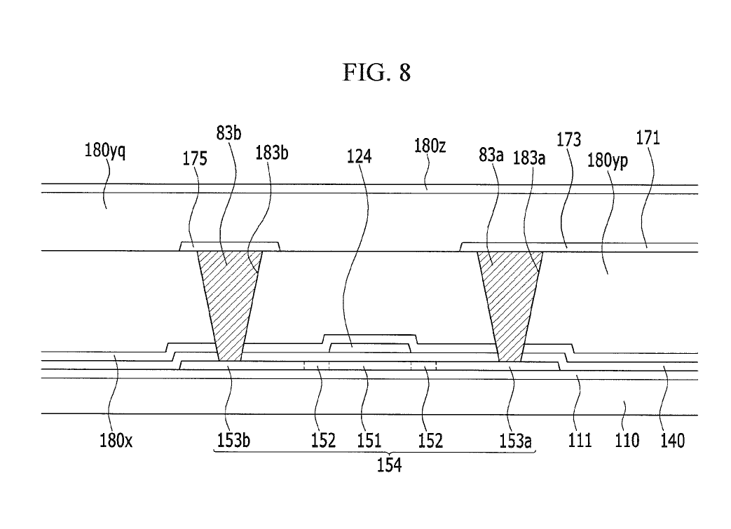

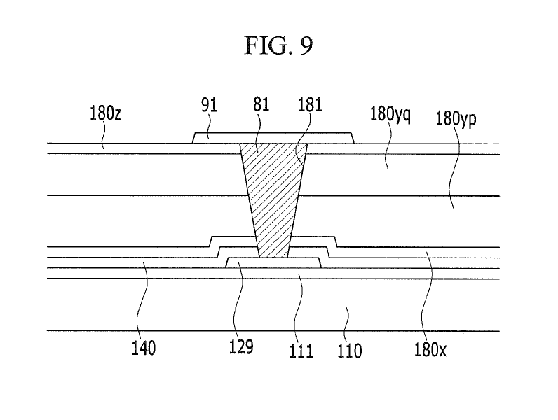

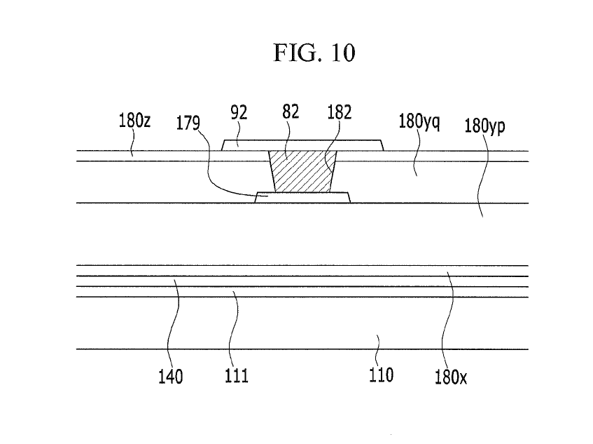

Hereinafter, another exemplary embodiment of a thin film transistor array panel according to the invention will be described with reference to FIGS. 6 to 10. FIG. 6 is a plan view of a another exemplary embodiment of thin film transistor array panel according to the invention, FIG. 7 is a cross-sectional view of the thin film transistor array panel of FIG. 6 taken along line VII-VII, FIG. 8 is a cross-sectional view of the thin film transistor array panel of FIG. 6 taken along line VIII-VIII, FIG. 9 is a cross-sectional view of the thin film transistor array panel of FIG. 6 taken along line IX-IX, and FIG. 10 is a cross-sectional view of the thin film transistor array panel of FIG. 6 taken along line X-X.

Referring to FIGS. 6 to 10, a blocking film 111 including silicon nitride (SiNx) or silicon oxide (SiO₂) is directly on an insulation substrate 110. The blocking film 111 may have a multilayered structure.

A semiconductor 154 including polysilicon is on the blocking film 111. The semiconductor 154 includes an extrinsic region including a conductive impurity and an intrinsic region substantially excluding the conductive impurity. The extrinsic region includes a heavily doped region having a high impurity concentration and a lightly doped region having a low impurity concentration.

The intrinsic region includes a channel region 151, the heavily doped extrinsic region includes a source region 153a and a drain region 153b on opposing sides of the channel region 151, and the lightly doped extrinsic region includes an intermediate region 152. The lightly doped extrinsic region 152 is respectively disposed between the intrinsic region 151 and the heavily doped extrinsic region 153a and 153b. The intermediate region 152 has a width taken parallel to the insulation substrate 110 smaller than a width of the channel region 151, the source region 153a and the drain region 153b. The lightly doped extrinsic region 152 is called a lightly doped drain region (“LDD region”). The LDD region 152 reduces or effectively prevents a leakage current or a punch through phenomenon of the TFT from occurring. The LDD region 152 may be replaced with an offset region without the impurity, and alternatively may be omitted. Herein, the impurity may include boron (B), gallium (Ga), and the like as a P-type conductive impurity, and include phosphorus (P), arsenic (As), and the like as an N-type impurity.

A gate insulating layer 140 including silicon nitride or silicon oxide is on the semiconductor 154 and the blocking film 111.

A plurality of gate conductors includes a plurality of gate lines 121 including gate electrodes 124, and a gate pad 129 having a wide area for connection with another layer or an external driving circuit, and a plurality of common voltage lines 125, are on the gate insulating layer 140.

The gate electrode 124 overlaps with the channel region 151 of the semiconductor 154.

A first passivation layer 180x is disposed on the gate conductors 121 and 125. The first passivation layer 180x may include an organic insulating material, an inorganic insulating material, or the like.

A second passivation layer 180y is disposed on the first passivation layer 180x, and includes a lower layer 180yp and an upper layer 180yq. The lower layer 180yp of the second passivation layer 180y includes the organic material and an upper surface thereof may be substantially flat. A data line 171 and a drain electrode 175 are on the upper surface of the lower layer 180yp of the second passivation layer 180y. The upper layer 180yq of the second passivation layer 180y covers the data line 171 and the drain electrode 175.

A fifth contact hole 183a and a sixth contact hole 183b exposing the source region 153a and the drain region 153b are extended completely through a thickness of the first passivation layer 180x, the lower layer 180yp of the second passivation layer 180y and the gate insulating layer 140. A third connection assistant member 83a and a fourth connection assistant member 83b are in the fifth contact hole 183a and the sixth contact hole 183b, respectively. The third connection assistant member 83a and the fourth connection assistant member 83b may entirely fill the fifth contact hole 183a and the sixth contact hole 183b, but may alternatively partially fill the fifth contact hole 183a and the sixth contact hole 183b. That is, the third connection assistant member 83a and the fourth connection assistant member 83b may be in a portion of the fifth contact hole 183a and/or the sixth contact hole 183b.

The source electrode 173 of the data line 171 is connected with the source region 153a through the fifth contact hole 183a, and the third connection assistant member 83a is disposed between the source region 153a and the source electrode 173. The third connection assistant member 83a is in a portion of the fifth contact hole 183a to electrically connect the source region 153a and the source electrode 173 to each other. Similarly, the drain electrode 175 is connected with the drain region 153b through the sixth contact hole 183b, and the fourth connection assistant member 83b is disposed between the drain region 153b and the drain electrode 175. The fourth connection assistant member 83b is in a portion of the sixth contact hole 183b to electrically connect the drain region 153b and the drain electrode 175 to each other.

The common electrode 131 is directly on the upper layer 180yq of the second passivation layer 180y. The common electrode 131 is electrically connected with the common voltage line 125 through the contact hole 184 to receive the predetermined voltage such as the common voltage Vcom and the like from the common voltage line 125. In the exemplary embodiment, the common electrode 131 may be substantially planar such as a plate on an entire surface of the insulation substrate 110.

The third passivation layer 180z is on the common electrode 131, and a pixel electrode 191 is on the third passivation layer 180z. The pixel electrode 191 may include a transparent conductive material such as ITO, IZO, or the like.

Similarly to the exemplary embodiment of the thin film transistor array panel described above with reference to FIGS. 1 to 5, a first contact hole 181 exposing the gate pad 129 is extended completely through a thickness of the first passivation layer 180x, the second passivation layer 180y, the third passivation layer 180z and the gate insulating layer 140. The first contact hole 181 may be a single opening and may have a planar profile of a polygon such as a square or the like, a circle, or an ellipse.

A second contact hole 182 exposing the data pad 179 is extended completely through the thickness of the upper layer 180yq of the second passivation layer 180y and the third passivation layer 180z. The second contact hole 182 may be a single opening and may have a planar profile of a polygon such as a square or the like, a circle, or an ellipse.

A plurality of the third contact holes 183 partially exposing the drain electrodes 175 are extended completely through the thickness of the upper layer 180yq of the second passivation layer 180y and the third passivation layer 180z. The fourth contact hole 184 partially exposing the common voltage lines 125 is extended completely through the thickness of the first passivation layer 180x and the second passivation layer 180y.

The pixel electrode 191 is electrically connected to the drain electrode 175 through the third contact hole 183 to receive data voltage. Although not shown, the thin film transistor array panel may further include a third connection assistant member disposed in a portion of the third contact hole 183. By the third connection assistant member, even though the depth of the third contact hole 183 becomes larger or the taper angle increases, the third connection assistant member partially filling the third contact hole 183 is included, thereby increasing reliability in the connection between the pixel electrode 191 and the drain electrode 175.

The pixel electrodes 191 includes a plurality of branch electrodes 193 having a longitudinal axis extending substantially parallel to each other and separated from each other in a direction transverse to the longitudinal axis, and lower and upper horizontal portions 192 connecting upper and lower end portions of the branch electrodes 193 to each other. The branch electrode 193 of the pixel electrode 191 may be bent along the longitudinal axis thereof, and may be parallel to the data line 171 in the plan view.

The pixel electrode 191 receiving the data voltage generates an electric field in the liquid crystal layer 3 (see FIG. 12) together with the common electrode 131 receiving the common voltage.

Similarly to the exemplary embodiment of the thin film transistor array panel described above with reference to FIGS. 1 to 5, the first connection assistant member 81 and the second connection assistant member 82 are in a portion of the first contact hole 181 and the second contact hole 182.

All of the many characteristics of the exemplary embodiment of the thin film transistor array panel described above with reference to FIGS. 1 to 5 may be applied to the exemplary embodiment of the thin film transistor array panel described above with reference to FIGS. 6 to 10.

In the case of an alternative exemplary embodiment of the film transistor array panel according to the invention, one of the gate driving circuit and the data driving circuit may be directly on the insulation substrate 110. In this case, one of the gate pad 129 and the data pad 179 may be directly connected with the driving circuit, one of the first contact hole 181 and the second contact hole 182 exposing the gate pad 129 and the data pad 179 may be omitted, and one of the first connection assistant member 81 and the second connection assistant member 82 may be omitted.

The aforementioned alternative exemplary embodiment is an exemplary embodiment for describing the invention and the many features of the invention may be applied to all the thin film transistor array panels where the two field generating electrodes are on the thin film transistor array panel.

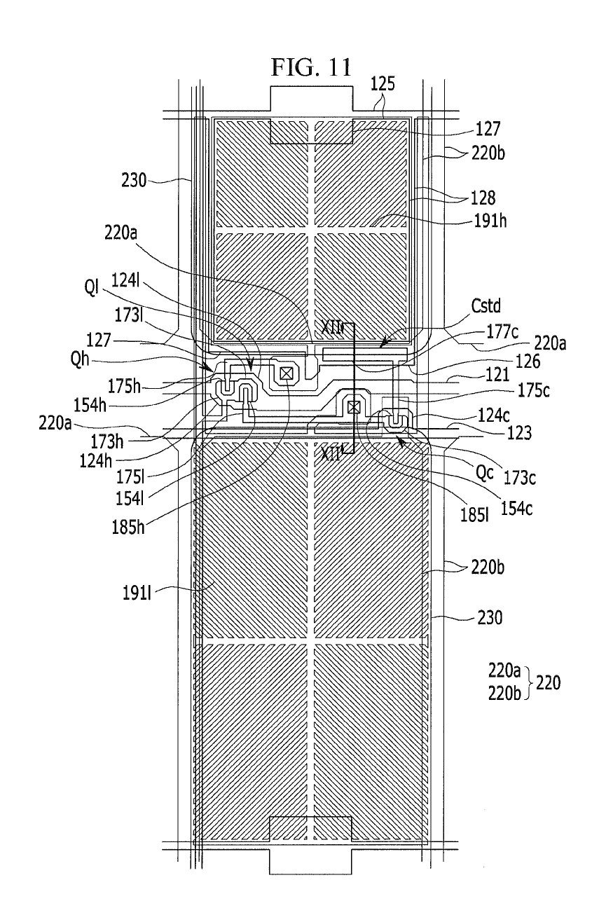

Hereinafter, an exemplary embodiment of a liquid crystal display according to the invention will be described with reference to FIGS. 11 and 12. FIG. 11 is a plan view of an exemplary embodiment of a liquid crystal display including a thin film transistor array panel according to the invention and FIG. 12 is a cross-sectional view of the liquid crystal display of FIG. 11 taken along line XII-XII.

An exemplary embodiment of the liquid crystal display including the thin film transistor array panel includes a thin film transistor array panel 100 and a common electrode panel 200 facing each other, a liquid crystal layer 3 interposed between the two display panels 100 and 200, and a pair of polarizers (not shown) attached to the outer surface of the display panels 100 and 200.

Hereinafter, the thin film transistor array panel 100 of the exemplary embodiment will be described.

A gate conductor including a plurality of gate lines 121, a plurality of voltage-reducing gate lines 123, and a plurality of common voltage lines 125 (otherwise referred to as storage electrode lines) are on an insulation substrate 110.

The gate lines 121 and voltage-reducing gate lines 123 have a longitudinal axis that mainly extends in a horizontal direction in the plan view and transfer gate signals. The gate line 121 includes a first gate electrode 124h and a second gate electrode 124l protruding downwards and upwards, respectively, and the voltage-reducing gate line 123 includes a third gate electrode 124c protruding upwards, in the plan view. The first gate electrode 124h and the second gate electrode 124l are continuous and connected to each other to form one protrusion extended from the gate line 121.

The storage electrode lines 125 also have a longitudinal axis that mainly extends in a horizontal direction in the plan view and transfer predetermined voltage such as common voltage and the like. The storage electrode lines 125 include storage electrodes 127 protruding upwards and downwards, a pair of vertical portions 128 extending downwards to be substantially vertical (or perpendicular) to the gate lines 121, and a horizontal portion 127 connecting ends of the pair of vertical portions 128. The horizontal portion 127 includes an extension 126 (otherwise referred to as a capacitance electrode) extending downwards.

A gate insulating layer 140 is on the gate conductors 121, 123 and 125.

A plurality of semiconductors 154h, 154l, 154c and 157, which may include amorphous or crystalline silicon, are on the gate insulating layer 140. The semiconductors 154h, 154l, 154c and 157 include first and second semiconductors 154h and 154l extending toward the first and second gate electrodes 124h and 124l and connected to each other, and a third semiconductor 154c connected with the second semiconductor 154l. The third semiconductor 154c extends to form a fourth semiconductor 157.

A plurality of ohmic contacts are on the semiconductors 154h, 154l, 154c, and 157. A first ohmic contact (not shown) is on the first semiconductor 154h, and a second ohmic contact 164b (not shown) and a third ohmic contact (not shown) are on the second semiconductor 154l and the third semiconductor 154c, respectively. The third ohmic contact extends to form a fourth ohmic contact 167.

A data conductor including a plurality of data lines 171, a plurality of first drain electrodes 175h, a plurality of second drain electrodes 175l and a plurality of third drain electrodes 175c is on the ohmic contacts 164b and 167.

The data lines 171 transfer data signals and have a longitudinal axis that mainly extends in a vertical direction in the plan view to cross the gate lines 121 and voltage-reducing gate lines 123. Each of the data lines 171 includes a first source electrode 173h and a second source electrode 173l forming a ‘W’ shape together by extending toward the first gate electrode 124h and the second gate electrode 124l, respectively.

The first drain electrode 175h, the second drain electrode 175l and the third drain electrode 175c include a wide first end portion and a rod-shaped second end portion. The rod-shaped second end portions of the first drain electrode 175h and the second drain electrode 175l are partially surrounded by the first source electrode 173h and the second source electrode 173l, respectively. The wide first end portion of the second drain electrode 175l further extends to form the third source electrode 173c have a curved ‘U’-lettered shape. A wide first end portion 177c of the third drain electrode 175c overlaps with the capacitance electrode 126 to form a voltage-reducing capacitor Cstd and the rod-shaped second end portion is partially surrounded by the third source electrode 173c.

The first, second and third gate electrodes 124h, 124l and 124c, the first, second and third source electrodes 173h, 173l and 173c, and the first, second and third drain electrodes 175h, 175l and 175c form first, second and third TFTs Qh, Ql and Qc together with first, second and third semiconductor islands 154h, 154l and 154c, respectively. A channel of the TFT is at each of the semiconductors 154h, 154l and 154c respectively between the source electrodes 173h, 173l and 173c and each of the drain electrodes 175h, 175l and 175c.

The semiconductors 154h, 154l, 154c and 157 have substantially the same planar shape as the data conductors 171, 175h, 175l and 175c and the ohmic contacts 1641 and 167 therebelow, except for a channel region respectively between the source electrodes 173h, 173l and 173c and the drain electrodes 175h, 175l and 175c. That is, exposed portions of the semiconductors 154h, 154l, 154c and 157 are not covered by the data conductors 171, 175h, 175l and 175c, and spaces are respectively between the source electrode 173h, 173l and 173c and the drain electrode 175h, 175l and 175c are disposed at the semiconductors 154h, 154l, 154c and 157.

A lower passivation layer 180p, which may include an inorganic insulator such as silicon nitride or silicon oxide, is on the data conductors 171, 175h, 175l and 175c and the exposed portions of the semiconductors 154h, 154l and 154c.

Color filters 230 are disposed on the lower passivation layer 180p. The color filters 230 are disposed at most of regions excluding regions including the first TFT Qh, the second TFT Ql and the third TFT Qc. However, the color filters 230 may have a longitudinal axis elongated in a vertical direction in the plan view along spaces between the adjacent data lines 171. Each of the color filters 230 may display one of the primary colors such as three primary colors of red, green and blue, and the like.

Light blocking members 220 are disposed at a region without the color filter 230 and overlapping a portion of the color filters 230. The light blocking member 220 is otherwise referred to as a black matrix and reduces or effectively prevents light leakage. The light blocking members 220 include portions that extend substantially parallel to the gate line 121 and the voltage-reducing gate line 123 and are extended upwards and downwards in the plan view. The light blocking members 220 include a first light blocking member 220a covering the regions including the first TFT Qh, the second TFT Ql and the third TFT Qc, and a second light blocking member 220b extending substantially parallel to the data line 171. A spacer 325 is on the light blocking member 220. Although not shown, the spacer 325 may include a plurality of sub-spacers having different heights.

An upper passivation layer 180q is on the color filter 230 and the light blocking members 220. The upper passivation layer 180q reduces or effectively prevents lifting of the color filter 230 and the light blocking member 220. The upper passivation layer 180q also suppresses contamination of the liquid crystal layer 3 due to an organic material such as a solvent flowing from the color filter 230, thereby reducing or effectively preventing a defect such as afterimage caused from driving the liquid crystal display.

A plurality of seventh contact holes 185h and a plurality of eighth contact holes 185l, which expose the wide first end portion of the first drain electrode 175h and the wide second end portion of the second drain electrode 175l, are extended completely through a thickness of the lower passivation layer 180p, the light blocking member 220 and the upper passivation layer 180q.

A plurality of pixel electrodes 191 are on the upper passivation layer 180q.

Each of the pixel electrodes 191 includes a first subpixel electrode 191h and a second subpixel electrode 191l which are separated from each other with the two gate lines 121 and 123 therebetween. The first and second subpixel electrodes 191h and 191l are respectively disposed above and below in a pixel area with respect to the gate lines 121 and 123. The first and second subpixel electrodes 191h and 191l are adjacent to each other in a column direction of the pixel area.

The overall shape of the first subpixel electrode 191h and the second subpixel electrode 191l is a quadrilateral such as a square. The shape includes a cross stem including a horizontal stem, and a vertical stem perpendicular to the horizontal stem. The quadrilateral shape is divided into four subregions by the horizontal stem and the vertical stem, and each subregion includes a plurality of minute branches. Each of the minute branches forms an angle of about 45 degrees or 135 degrees with the gate line or the horizontal stem.

The first subpixel electrode 191h and the second subpixel electrode 191l include an outer stem at an outside periphery. A vertical portion of the outer stem extends substantially parallel to the data line 171 to prevent capacitive bonding, that is, a capacitive coupling between the data line 171 and the first subpixel electrode 191h and the second subpixel electrode 191l.

The first subpixel electrode 191h and the second subpixel electrode 191l receive data voltage from the first drain electrode 175h and the second drain electrode 175l through the seventh contact hole 185h and the eighth contact hole 185l. A sixth connection assistant member (not shown) and a seventh connection assistant member 85l are disposed in a portion of the seventh contact hole 185h and the eighth contact hole 185l. By the sixth connection assistant member and the seventh connection assistant member 85l filling a portion of the seventh contact hole 185h and the eighth contact hole 185l, even though the depths of the seventh contact hole 185h and the eighth contact hole 185l become larger or the taper angle increases, it is possible to increase reliability in the connection between the first subpixel electrode 191h and the second subpixel electrode 191l and the first drain electrode 175h and the second drain electrode 175l, respectively.

The first subpixel electrode 191h and the second subpixel electrode 191l to which the data voltage is applied from the first drain electrode 175h and the second drain electrode 175l, generate an electric field together with a common electrode 270 of the common electrode panel 200 to determine a direction of liquid crystal molecules 31 of the liquid crystal layer 3 between the two electrodes 191 and 270. As described above, luminance of light transmitting the liquid crystal layer 3 varies according to the determined direction of the liquid crystal molecules 31.

Side edges of respective minute branches distort the electric field to make a horizontal component determining a tilt direction of the liquid crystal molecules 31. The horizontal component of the electric field is substantially horizontal with respect to the side of the minute branch. Accordingly, the liquid crystal molecules 31 are inclined parallel to a longitudinal axis (otherwise referred to as a length direction) of the minute branch. Since the first subpixel electrode 191h and the second subpixel electrode 191l include four subregions having different length directions of the minute branches, the inclined directions of the liquid crystal molecules 31 are substantially four directions and four domains having different alignment directions of the liquid crystal molecule 31 are formed in the liquid crystal layer 3. As described above, when the inclined directions of the liquid crystal molecules 31 are verified, a reference viewing angle of the liquid crystal display increases.

The first subpixel electrode 191h and the common electrode 270 form a first liquid crystal capacitor together with the liquid crystal layer 3 therebetween, and the second subpixel electrode 191l and the common electrode 270 form a second liquid crystal capacitor together with the liquid crystal layer 3 therebetween to maintain the voltage applied even after the first and second TFTs Qh and Ql are turned off.

The first and second subpixel electrodes 191h and 191l overlap with the storage electrode line 125 in addition to the storage electrode 127 to form the first and second storage capacitors, and the first and second storage capacitors reinforce voltage storage capacity of the first and second liquid crystal capacitors, respectively.

The capacitance electrode 126 and the extension 177c of the third drain electrode 175c overlap with each other with the gate insulating layer 140 and the semiconductor layers 157 and 167 therebetween to form the voltage-reducing capacitor Cstd. In an alternative exemplary embodiment of the invention, the layers 157 and 167, which are disposed between the capacitance electrode 126 and the extension 177c of the third drain electrode 175c forming the voltage-reducing capacitor Cstd, may be omitted.

A lower alignment layer (not shown) is on the pixel electrode 191 and the exposed upper passivation layer 180q. The lower alignment layer may be a vertical alignment layer.

Hereinafter, the common electrode panel 200 will be described.

The common electrode 270 is on an insulation substrate 210. An upper alignment layer (not shown) is on the common electrode 270. The upper alignment layer may be a vertical alignment layer.

Polarizers (not shown) are provided at the outer surfaces of the two display panels 100 and 200, transmissive axes of the two polarizers are perpendicular to each other and one of the transmissive axes may be parallel to the gate line 121.

The liquid crystal layer 3 has negative dielectric anisotropy and the liquid crystal molecules 31 of the liquid crystal layer 3 are aligned so that a longitudinal axis thereof is vertical (e.g., perpendicular) to the surfaces of the two display panels 100 and 200 while the electric field is not applied. Accordingly, incident light may not transmit through crossed polarizers and is blocked while the electric field is not applied.

As described above, since the first subpixel electrode 191h and the second subpixel electrode 191l to which the data voltage is applied generate the electric field together with the common electrode 270 of the common electrode panel 200, the liquid crystal molecules 31 of the liquid crystal layer 3, which are aligned so as to be substantially vertical (e.g., perpendicular) to the surfaces of the two electrodes 191 and 270 while the electric field is not applied, are inclined in a horizontal direction (e.g., parallel) to the surfaces of the two electrodes 191 and 270 and the luminance of the light transmitting the liquid crystal layer 3 varies according to the inclined degree of the liquid crystal molecules 31.

Although not shown, like the exemplary embodiments of the thin film transistor array panel described above, the connection assistant members filling a portion of the contact holes exposing the gate pad and the data pad are included, such that it is possible to increase reliability in the connection between the gate pad and the data pad exposed by the contact holes and the conductors thereon.

In an exemplary embodiment, the first pixel electrode 191h and the second pixel electrode 191l may be connected with the voltage-reducing capacitor, but d the features of the invention may be applied to all the thin film transistor array panels including the pixel electrodes having the plurality of minute branches as shown in FIG. 11.

As described above, since the exemplary embodiment of the liquid crystal display including a thin film transistor array panel according to the invention includes the connection assistant members filling a portion of the contact holes for connecting the two conductive layers disposed on different layers, even though the depth of the contact hole becomes larger or the taper angle increases, the connection assistant member is disposed between the lower conductive layer exposed through the contact hole and the upper conductive layer overlapping the contact hole to connect the lower conductive layer and the upper conductive layer through the connection assistant member, such that the lower conductive layer exposed through the contact hole and the upper conductive layer overlapping the contact hole may be firmly connected to each other.

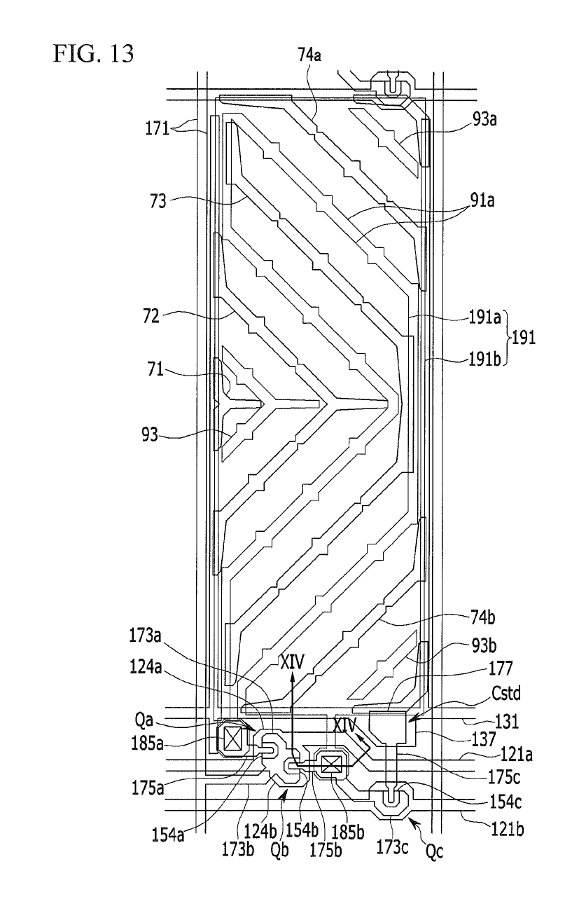

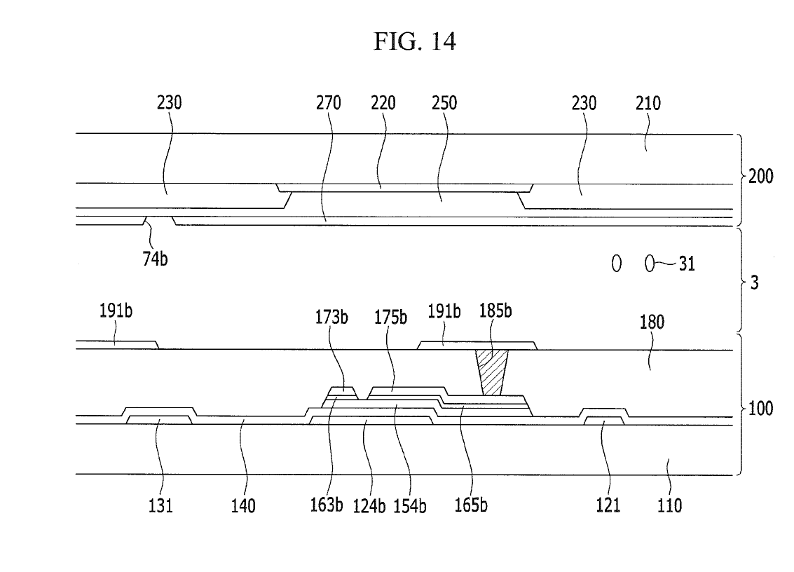

Hereinafter, yet another exemplary embodiment of a liquid crystal display according to yet the invention will be described with reference to FIGS. 13 and 14. FIG. 13 is a plan view of another exemplary embodiment of a liquid crystal display including a thin film transistor array panel according to yet the invention and FIG. 14 is a cross-sectional view of the liquid crystal display of FIG. 13 taken along line XIV-XIV.

Referring to FIGS. 13 and 14, an exemplary embodiment of a liquid crystal display includes a thin film transistor array panel 100 and a common electrode panel 200 facing each other, and a liquid crystal layer 3 interposed between the two display panels 100 and 200.

First, the thin film transistor array panel 100 will be described.

A gate conductor including gate lines 121 and capacitor voltage lines 131 are on an insulation substrate 110. The gate line 121 includes first, second and third gate electrodes 124a, 124b and 124c and end portions (not shown).

The capacitor voltage line 131 transfers constant capacitor voltage and includes a capacitance electrode 137 having a wide area in a vertical direction in the plan view.

A gate insulating layer 140 is on the gate conductors 121 and 131. Semiconductors are on the gate insulating layer 140. The semiconductors include a plurality of first, second and third semiconductors 154a, 154b and 154c extending toward the first, second and third gate electrodes 124a, 124b and 124c. The first, second, and third semiconductors 154a, 154b and 154c are disposed on the first to third gate electrodes 124a to 124c, respectively. The third semiconductor 154c extends to form a fourth semiconductor (not shown).

The semiconductors 154a, 154b and 154c may include an organic semiconductor. The organic semiconductor may include a tetracene or pentacene compound, e.g., a compound including a substituent of tetracene or pentacene, and may include an oligothiophene including 4 to 8 thiophenes connected to each other at the 2 and 5 positions of a thiophene ring (e.g., those positions adjacent S). The organic semiconductor may include polythienylenevinylene, poly(3-hexylthiophene), polythiophene, phthalocyanine, metallized phthalocyanine, or a halogenated derivative thereof. Further, the organic semiconductor may further include perylenetetracarboxylic dianhydride (“PTCDA”), naphthalenetetracarboxylic dianhydride (“NTCDA”), or an imide derivative thereof. The organic semiconductor may include a perylene, a coronene compound, or a substituent thereof.

Ohmic contacts 163b and 165b are disposed on the semiconductors 154a, 154b and 154c. When the semiconductors 154a, 154b and 154c are oxide semiconductors, the ohmic contacts may be omitted.

A data conductor including a plurality of data lines 171, a plurality of first electrode members 175a, a plurality of second electrode members 173c and 175b and a third electrode member 175c is on the ohmic contacts 163b and 165b and the gate insulating layer 140.

The data line 171 includes a wide end portion (not shown) for connecting another layer or an external driving circuit with a plurality of first and second source electrodes 173a and 173b.

The first electrode members 175a form a first drain electrode, the second electrode members include a second drain electrode 175b and a third source electrode 173c connected with each other, and the third electrode member 175c forms a third drain electrode 175c.

The first to third drain electrodes 175a, 175b and 175c include wide first end portions and trod-shaped second end portions, respectively. The rod-shaped second end portions of the first, second and third drain electrodes 175a, 175b and 175c are partially surrounded by the first, second and third source electrodes 173a, 173b and 173c. The third source electrode 173c is connected to the wide second end portion of the second drain electrode 175b.

The semiconductors 154a, 154b and 154c have substantially the same planar shape as the data line 171, the first to third drain electrodes 175a, 175b and 175c, and the ohmic contacts 163b and 165b therebelow. However, the semiconductors 154a, 154b and 154c include exposed portions not covered by the data line 171 and the drain electrodes 175a to 175c. Spaces are between the source electrodes 173a to 173c and the drain electrodes 175a to 175c, respectively.

The first, second and third gate electrodes 124a, 124b and 124c, the first, second and third source electrodes 173a, 173b and 173c, and the first, second and third drain electrodes 175a, 175b and 175c form first, second and third TFTs Qa, Qb and Qc together with first, second and third semiconductor islands 154a, 154b and 154c, respectively and a channel of the TFT is formed at each of the semiconductors 154a, 154b and 154c between each of the source electrodes 173a, 173b and 173c and each of the drain electrodes 175a, 175b and 175c, respectively.

A passivation layer 180 is on the data conductors 171, 175a, 175b and 175c and the exposed portions of the semiconductors 154a, 154b and 154c. The passivation layer 180 includes an inorganic insulator such as silicon nitride or silicon oxide.

A plurality of ninth contact holes 185a and tenth contact holes 185b exposing the wide end portions of the first drain electrodes 175a and the wide end portions of the second drain electrodes 175b, respectively are extended completely through the passivation layer 180.

A pixel electrode 191 including first and second subpixel electrodes 191a and 191b, and contact assistant members (not shown) are on the passivation layer 180. The pixel electrode 191 and the contact assistant members may include a transparent material such as ITO and IZO.

The first subpixel electrode 191a and the second subpixel electrode 191b are disposed with a gap 91a therebetween. The first subpixel electrode 191a is surrounded by the second subpixel electrode 191b. The second subpixel electrode 191b includes a plurality of cutouts 93, 93a, and 93b.

The first/second subpixel electrodes 191a and 191b are connected with the first and second drain electrodes 175a and 175b through the ninth and tenth contact holes 185a and 185b to receive data voltage from the first and second drain electrodes 175a and 175b, respectively. An eighth connection assistant member (not shown) and a ninth connection assistant member 85b are disposed in a portion of the ninth contact hole 185a and the tenth contact hole 185b. By the eighth connection assistant member and the ninth connection assistant member 85b filling a portion of the ninth contact hole 185a and the tenth contact hole 185b, even though the depths of the ninth contact hole 185a and the tenth contact hole 185b become larger or the taper angle increases, it is possible to increase reliability in the connection between the first subpixel electrode 191a and the second subpixel electrode 191b and the first drain electrode 175a and the second drain electrode 175b.

The first and second subpixel electrodes 191a and 191b where the data voltage is applied from the first and second drain electrodes 175a and 175b generate an electric field together with the common electrode 270 of the common electrode panel 200 to determine a direction of liquid crystal molecules 31 of the liquid crystal layer 3 between two electrodes 191 and 270. As described above, luminance of light transmitting the liquid crystal layer 3 varies according to the determined direction of the liquid crystal molecules 31.

The capacitance electrode 137 and the wide end portion 177 of the third drain electrode 175c overlap with each other with the gate insulating layer 140 and the semiconductor layer therebetween to form a voltage-reducing capacitor Cstd. As described above, by forming the voltage-reducing capacitor Cstd using the gate conductor and the data conductor, an additional process for forming the voltage-reducing capacitor Cstd is not required, thereby simplifying a manufacturing process of the liquid crystal display. Since only the gate insulating layer 140 and the semiconductor layer are disposed between the two electrodes of the voltage-reducing capacitor Cstd, capacitance of the voltage-reducing capacitor Cstd may increase as compared with the case where the passivation layer 180 is disposed between the two electrodes.

A lower alignment layer (not shown) is formed on the pixel electrode 191, the contact assistant member and the passivation layer 180. The lower alignment layer may be a vertical alignment layer.

Hereinafter, the common electrode panel 200 will be described.

A light blocking member 220 is formed on an insulation substrate 210. The light blocking member 220 is also referred to as a black matrix and reduces or effectively prevents light leakage.

A plurality of color filters 230 are on the insulation substrate 210 of a region defined by the light blocking member 220.

The color filter 230 may display one of primary colors such as three primary colors of red, green and blue, and the like, and may include an organic material including a pigment displaying one of the three primary colors. In the exemplary embodiment, the color filter 230 is in the upper panel 200, but an alternative exemplary embodiment of the liquid crystal display according to the invention may include the color filters 230 in the lower panel 100. Further, in the exemplary embodiment, the color filters 230 may be formed by a photolithographic process, but an alternative exemplary embodiment of the liquid crystal display according to the invention may include the color filters 230 formed by an inkjet printing method. In this case, barriers such as including a black pigment, defining a region where ink for color filters 230 is dropped may be included in the display panels 100 and 200, and the barriers may serve as the light blocking member for reducing or effectively preventing light leakage with the black pigment.

In the exemplary embodiment, the light blocking member 220 is in the upper panel 220, but the exemplary embodiment of the liquid crystal display according to the invention may include the light blocking member 220 in the lower panel 100. Further, as described above, when the color filters 230 are formed by the inkjet printing method, the light blocking member 220 may also serve as the barriers defining a portion where ink for color filters 230 is dropped.

An overcoat 250 is on the light blocking member 220 and the color filter 230. The common electrode 270 is on the overcoat 250. The common electrode 270 includes a plurality of cutout 71, 72, 73, 74a and 74b. One of the cutout 71, 72, 73, 74a and 74b faces one pixel electrode 191 and each of the cutouts 71, 72, 73, 74a and 74b is disposed between the gap of the pixel electrode and the cutout of the pixel electrode.

An upper alignment layer (not shown) is on the common electrode 270. The upper alignment layer may be a vertical alignment layer.

The liquid crystal layer 3 has negative dielectric anisotropy and the liquid crystal molecules 31 of the liquid crystal layer 3 are aligned so that a longitudinal axis thereof is vertical to the surfaces of the two display panels 100 and 200 while the electric field is not applied.

When the common voltage is applied to the common electrode 270 and the data voltage is applied to the pixel electrode 191, an electric field which is substantially vertical to the surfaces of the display panels 100 and 200 is generated. The liquid crystal molecules 31 respond to the electric field to change the direction so that the longitudinal axis thereof is vertical to the direction of the electric field. Hereinafter, the pixel electrode 191 and the common electrode 270 are collectively referred to as field generating electrodes.

The respective cutouts of the field generating electrodes 191 and 270, and the sides of the gap and of the pixel electrode 191 distort the electric field to make a horizontal component for determining a tilt direction of the liquid crystal molecules 31. The horizontal component of the electric field is substantially vertical to the respective cutouts of the field generating electrodes 191 and 270, the side of the gap of the pixel electrode 191, and the sides of the pixel electrode 191.

Respective cutouts of the field generating electrodes 191 and 270 and the gap of the pixel electrode 191 divide the pixel electrode 191 into a plurality of sub-areas. Each of the sub-areas has two major edges forming an oblique angle with a major edge of the pixel electrode 191. Most of the liquid crystal molecules 31 in each of the sub-areas are inclined in a direction vertical (e.g. perpendicular) to the major edge, such that the inclined directions are substantially four directions. As described above, when the inclined directions of the liquid crystal molecule 31 are verified, a reference viewing angle of the liquid crystal display increases.

Although not shown, like the exemplary embodiments of the thin film transistor array panel described above, the connection assistant members filling a portion of the contact holes exposing the gate pad and the data pad are included, such that it is possible to increase reliability in the connection between the gate pad and the data pad exposed by the contact holes and the conductors such as the pixel electrode thereon.

In an exemplary embodiment, the first pixel electrode 191a and the second pixel electrode 191b may be connected with the voltage-reducing capacitor, but the features of the invention may be applied to all the thin film transistor array panels including the pixel electrode divided into the plurality of sub-areas with the plurality of cutouts in the field generating electrodes as shown in FIG. 13.

As described above, since the exemplary embodiment of the liquid crystal display including a thin film transistor array panel according to the invention includes the connection assistant members filling a portion of the contact holes for connecting the two conductive layers disposed on different layers, even though the depth of the contact hole becomes larger or the taper angle increases, the connection assistant member is disposed between the lower conductive layer exposed through the contact hole and the upper conductive layer overlapping the contact hole to connect the lower conductive layer and the upper conductive layer through the connection assistant member, such that the lower conductive layer exposed through the contact hole and the upper conductive layer overlapping the contact hole may be firmly connected to each other.

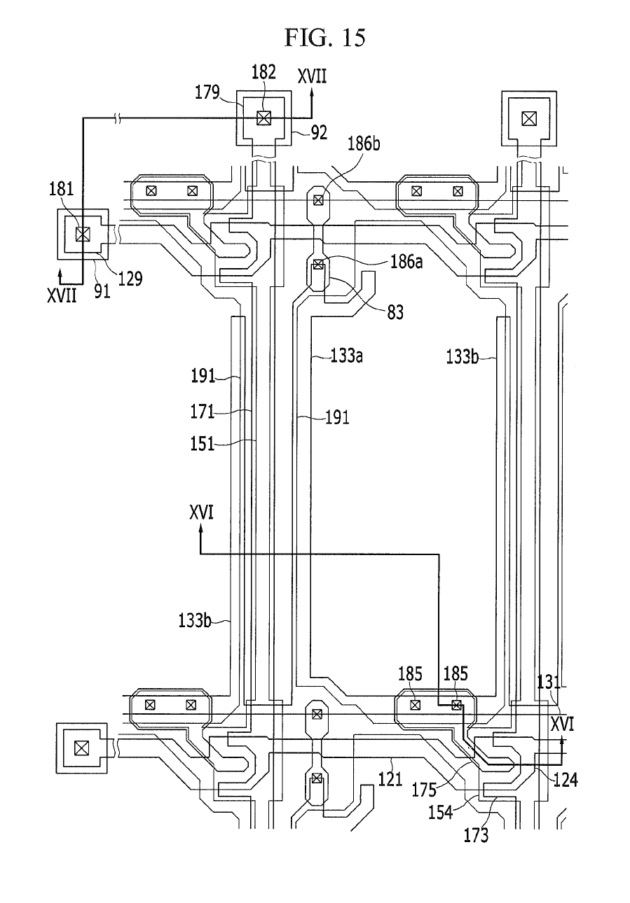

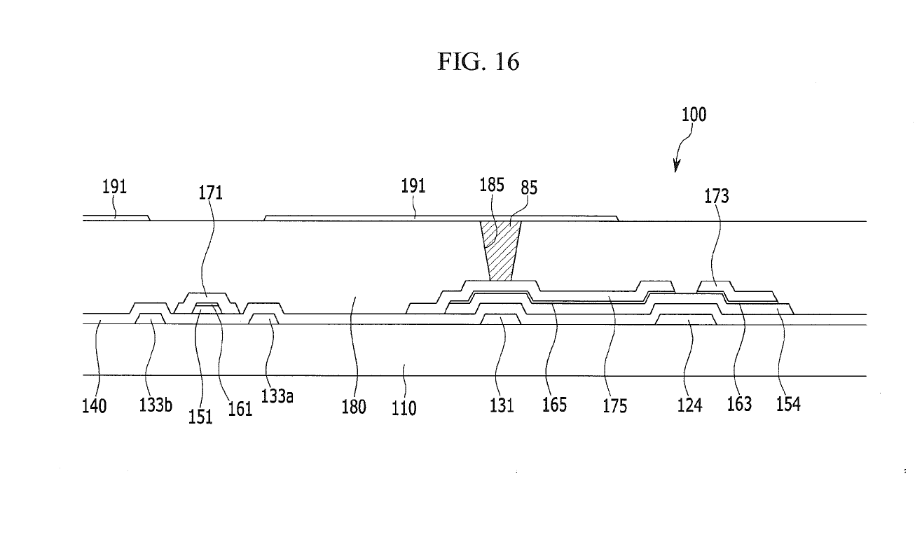

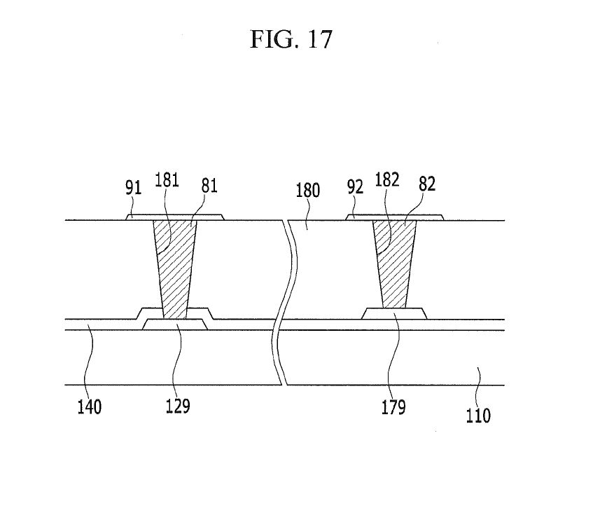

Hereinafter, yet another exemplary embodiment of a thin film transistor array panel according to the invention will be described with reference to FIGS. 15 to 17. FIG. 15 is a plan view of yet another exemplary embodiment of a thin film transistor array panel according to the invention, FIG. 16 is a cross-sectional view of the thin film transistor array panel of FIG. 15 taken along line XVI-XVI, and FIG. 17 is a cross-sectional view of the thin film transistor array panel of FIG. 15 taken along line XVII-XVII.

A plurality of gate lines 121 and a plurality of storage electrode lines 131 are on an insulation substrate 110 including transparent glass or plastic.

The gate lines 121 transfer gate signals and have a longitudinal axis which mainly extends in a horizontal direction in the plan view. Each of the gate lines 121 includes a plurality of gate electrodes 124 protruding downwards from a main portion of the gate line 121 and a gate pad 129 for connection with another layer or an external driving circuit.

The storage electrode lines 131 receive predetermined voltage and include stem lines having a longitudinal axis extending to be substantially parallel to the gate lines 121 and plural pairs of first and second storage electrodes 133a and 133b branched from the stem lines.

A gate insulating layer 140 including silicon nitride (SiNx) or silicon oxide (SiOx) is on the gate line 121 and the storage electrode line 131.

Semiconductors 151 and 154 are on the gate insulating layer 140. The semiconductors 151 and 154 have a longitudinal axis that mainly extends in a vertical direction in the plan view and include protrusions 154 protruding toward the gate electrodes 124. A plurality of ohmic contacts 161, 163 and 165 are on the semiconductors 151 and 154. The ohmic contacts 163 and 165 form a pair and are disposed on the semiconductor protrusions 154.

A plurality of data lines 171 and a plurality of drain electrodes 175 are on the gate insulating layer 140.

The data lines 171 transfer data signals and have a longitudinal axis that mainly extends in a vertical direction in the plan view to cross the gate lines 121. Each data line 171 includes a plurality of source electrodes 173 extending toward the gate electrode 124 and curved in a J-lettered shape in the plan view and a data pad 179 for connection with another layer or an external driving circuit.

One gate electrode 124, one source electrode 173 and one drain electrode 175 form one TFT together with the semiconductor 154, and a channel of the TFT is at the semiconductor protrusion 154 exposed between the source electrode 173 and the drain electrode 175.

A passivation layer 180 is on the data line 171, the drain electrode 175 and the exposed portion of the semiconductor 154.

An eleventh contact hole 185 exposing the drain electrode 175 is extended completely through a thickness of the passivation layer 180.

An eleventh connection assistant member 85 is disposed in a portion of the eleventh contact hole 185.

A plurality of pixel electrodes 191 are on the passivation layer 180. The plurality of pixel electrodes 191 may include a transparent conductive material such as ITO, IZO, or the like.

The pixel electrode 191 is physically and electrically connected with the drain electrode 175 through the eleventh contact hole 185 and receives the data voltage from the drain electrode 175.

A eleventh connection assistant member 85 is disposed in a portion of the eleventh contact hole 185. By the eleventh connection assistant member 85 filling a portion of the eleventh contact hole 185, even though the depth of the eleventh contact hole 185 becomes larger or a taper angle increases, it is possible to increase reliability in the connection between the pixel electrode 191 and the drain electrode 175.

The pixel electrode 191 to which the data voltage is applied generates an electric field together with a common electrode (not shown) of another display panel (not shown) receiving common voltage to determine a direction of liquid crystal molecules (not shown) of a liquid crystal layer (not shown) between the two electrodes.

The pixel electrode 191 and the drain electrode 175 connected thereto overlap with the storage electrode line 131 in addition to the storage electrodes 133a and 133b. The pixel electrode 191, the drain electrode 175 connected thereto, and the storage electrode line 131 overlap with each other to form a storage capacitor and the storage capacitor reinforces voltage storage capacity of a liquid crystal capacitor.

A connection assistant member 83 (also referred to as a connection bridge) crosses the gate line 121 in the plan view and is connected to an exposed portion of the storage electrode line 131 through the contact holes 186a and 186b disposed on opposite sides with respect to the gate line 121 therebetween. The storage electrode line 131 in addition to the storage electrodes 133a and 133b may be used for repairing a defect of the gate line 121, the data line 171 or the TFT together with the connection bridge 83.

Referring to FIG. 17, like the exemplary embodiment of the thin film transistor array panel described above, the connection assistant members 81 and 82 filling a portion of the contact holes 181 and 182 exposing the gate pad 129 and the data pad 179 are included, such that it is possible to increase reliability in the connection between the gate pad 129 and the data pad 179 exposed by the contact holes and the connection members 81 and 82 thereon.

As described above, since the exemplary embodiment of the thin film transistor array panel according to the invention includes the connection assistant members filling a portion of the contact holes for connecting the two conductive layers disposed on different layers from each other, even though the depth of the contact hole becomes larger or the taper angle increases, the connection assistant member is disposed between the lower conductive layer exposed through the contact hole and the upper conductive layer overlapping the contact hole to connect the lower conductive layer and the upper conductive layer through the connection assistant member, such that the lower conductive layer exposed through the contact hole and the upper conductive layer overlapping the contact hole may be firmly connected to each other.

All of the many features of the exemplary embodiments of the thin film transistor described above may be applied to the exemplary embodiment of the thin film transistor array panel in FIGS. 15 to 17. The aforementioned connection assistant members 81, 82, 83a, 83b, 85l, 85b and 85 may include any one of molybdenum (Mo), copper (Cu), aluminum (Al), nickel (Ni), platinum (Pt), gold (Au), silver (Ag) and chromium (Cr).

In an exemplary embodiment, the connection assistant members 81, 82, 83a, 83b, 85l, 85b and 85 may be formed by an inkjet method using a laser. The method is performed by the inkjet method, but when a droplet is dropped from an inkjet head, the laser is irradiated to volatilize a portion of solvent and dry and solidify a portion of the droplet, such that a desired metal layer may be dropped even in a region having a narrow width like the contact holes 181, 182, 183a and 183b.

In an exemplary embodiment, the connection assistant members 81, 82, 83a, 83b, 85l, 85b and 85 may be formed by using needles. In the method, the connection assistant members 81, 82, 83a, 83b, 85l, 85b and 85 are formed in the contact holes 181, 182, 183a, 183b, 185h, 185l, 185a, 185b and 185 by using the needles ejecting a paste including a metallic material constituting the connection assistant members 81, 82, 83a, 83b, 85l, 85b and 85. By controlling an area of an ejecting part of the needle and an amount of the paste ejected through the needle, a desired metal layer may be formed even in a region having a narrow width like the contact holes 181, 182, 183a, 183b, 185h, 185l, 185a, 185b and 185.

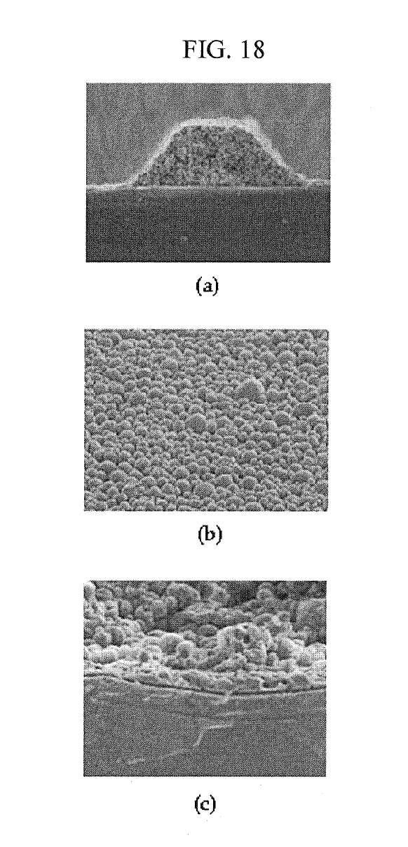

As described above, when the connection assistant members 81, 82, 83a, 83b, 85l, 85b, 85 are formed by using the droplet or paste type metallic material, metallic particles having small sizes may have a subsequent stacked form. The exemplary embodiments described above is shown in FIG. 18. FIGS. 18(a) to 18(c) are photographs illustrating an exemplary embodiment of forming a metal layer using a droplet or paste type metallic material. FIG. 18(a) is a cross-sectional photograph, FIG. 18(b) is a photograph of an upper surface, and FIG. 18(c) is an enlarged photograph of the cross section. Referring to FIGS. 18(a) to (c), in the case where the metal layer is formed by using the droplet or paste type metallic material, the metal layer is formed by continuously combining the metallic particles having small sizes.

Accordingly, in the case where the connection assistant members 81, 82, 83a, 83b, 85l, 85b and 85 of the exemplary embodiments of thin film transistor array panels according to the invention are formed by using the droplet or paste type metallic material, the metallic particles having small sizes may have a stacked form.

In another exemplary embodiment, the connection assistant members 81, 82, 83a, 83b, 85l, 85b and 85 of the thin film transistor array panel according to the present invention may be formed by using an electroless plating method. In detail, after a metal seed layer is formed, the metal layer is grown from the seed layer.

As described above, when the connection assistant members 81, 82, 83a, 83b, 85l, 85b and 85 are formed by using the electroless plating method, the connection assistant members 81, 82, 83a, 83b, 85l, 85b and 85 may have a double-layered structure divided into a lower seed layer and an upper growth layer.

In the exemplary embodiments of the thin film transistor array panel, any one of the two field generating electrodes overlapping with each other is a plate shape and the other electrode has branches, but the invention may be applied to all the other types of thin film transistor array panels having two field generating electrodes in one display panel.

Further, in the exemplary embodiments of the thin film transistor array panel, the two field generating electrodes overlapping with each other are in the thin film transistor array panel, but even though the two field generating electrodes are shown in the thin film transistor array panel, the invention may be applied to all types of thin film transistor array panels including the thin film transistor including the polysilicon layer.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A thin film transistor array panel, comprising:
an insulation substrate;
a gate line on the insulation substrate;
a gate insulating layer on the gate line;
a data line on the gate insulating layer;
a first insulating layer on the data line and including a first contact hole which exposes a portion of the data line;
a first connection assistant member in the first contact hole; and
further comprising a first field generating electrode on the first insulating layer,
wherein the first field generating electrode is in connection with the exposed portion of the data line through the first connection assistant member.

2. The thin film transistor array panel of claim 1, wherein:
the gate line includes a gate pad,
the data line includes a data pad,
further comprising:
a second contact hole in the first insulating layer and the gate insulating layer, the second contact hole exposing the gate pad,
a third contact hole in the first insulating layer, the third contact hole exposing the data pad,
a second connection assistant member in the second contact hole, and
a third connection assistant member in the third contact hole.

3. The thin film transistor array panel of claim 2, further comprising:
a first connecting member which overlaps the second contact hole, and in electrical connection with the gate pad through the second connection assistant member; and
a second connecting member which overlaps the third contact hole, and in electrical connection with the data pad through the third connection assistant member.

4. The thin film transistor array panel of claim 3, further comprising:
a second insulating layer on the first field generating electrode; and
a second field generating electrode on the second insulating layer,
wherein the first connecting member and the second connecting member are on a same layer as one of the first field generating electrode and the second field generating electrode.

5. The thin film transistor array panel of claim 4, wherein:
one of the first connection assistant member, the second connection assistant member and the third connection assistant member includes one of molybdenum (Mo), copper (Cu), aluminum (Al), nickel (Ni), platinum (Pt), gold (Au), silver (Ag) and chromium (Cr).

6. The thin film transistor array panel of claim 4, wherein:
one of the first connection assistant member, the second connection assistant member and the third connection assistant member is respectively in the first contact hole, the second contact hole and the third contact hole by an inkjet printing method using a laser.

7. The thin film transistor array panel of claim 4, wherein:
one of the first connection assistant member, the second connection assistant member and the third connection assistant member is in respectively in the first contact hole, the second contact hole and the third contact hole by a paste method using a needle.

8. The thin film transistor array panel of claim 4, wherein:
at least one of the first connection assistant member, the second connection assistant member and the third connection assistant member in respectively in the first contact hole, the second contact hole and the third contact hole by collecting small metallic particles.

9. The thin film transistor array panel of claim 4, wherein:
one of the first connection assistant member, the second connection assistant member and the third connection assistant member is in respectively in the first contact hole, the second contact hole and the third contact hole by an electroless plating method.

10. The thin film transistor array panel of claim 4, wherein:
one of the first connection assistant member, the second connection assistant member and the third connection assistant member has a multi-layered structure including a lower seed layer and an upper plating layer.

11. The thin film transistor array panel of claim 2, wherein:
one of the first connection assistant member, the second connection assistant member and the third connection assistant member includes one of molybdenum (Mo), copper (Cu), aluminum (Al), nickel (Ni), platinum (Pt), gold (Au), silver (Ag) and chromium (Cr).

12. The thin film transistor array panel of claim 2, wherein:
one of the first connection assistant member, the second connection assistant member, and the third connection assistant member is respectively in the first contact hole, the second contact hole and the third contact hole by an inkjet printing method using a laser.

13. The thin film transistor array panel of claim 2, wherein:
one of the first connection assistant member, the second connection assistant member and the third connection assistant member is respectively in the first contact hole, the second contact hole and the third contact hole by a paste method using a needle.

14. The thin film transistor array panel of claim 2, wherein:
one of the first connection assistant member, the second connection assistant member and the third connection assistant member is respectively in the first contact hole, the second contact hole and the third contact hole by collecting small metallic particles.

15. The thin film transistor array panel of claim 2, wherein:
one of the first connection assistant member, the second connection assistant member and the third connection assistant member is respectively in the first contact hole, the second contact hole and the third contact hole by an electroless plating method.

16. The thin film transistor array panel of claim 2, wherein:
one of the first connection assistant member, the second connection assistant member and the third connection assistant member has a multi-layered structure including a lower seed layer and an upper plating layer.

17. The thin film transistor array panel of claim 1, wherein:
the first connection assistant member includes one of molybdenum (Mo), copper (Cu), aluminum (Al), nickel (Ni), platinum (Pt), gold (Au), silver (Ag) and chromium (Cr).

18. The thin film transistor array panel of claim 1, wherein:
the first connection assistant member is in the first contact hole by an inkjet printing method using a laser.

19. The thin film transistor array panel of claim 1, wherein:
the first connection assistant member is in the first contact hole by a paste method using a needle.

20. The thin film transistor array panel of claim 1, wherein:
the first connection assistant member is in the first contact hole by collecting small metallic particles.

21. The thin film transistor array panel of claim 1, wherein:
the first connection assistant member is in the first contact hole by an electroless plating method.

22. The thin film transistor array panel of claim 1, wherein:
the first connection assistant member has a multi-layered structure including a lower seed layer and an upper plating layer.

23. A thin film transistor array panel, comprising:
an insulation substrate;
a semiconductor on the insulation substrate and including a channel region, a source region and a drain region;
a gate insulating layer on the semiconductor;
a gate line on the gate insulating layer and including a gate electrode;
a first insulating layer on the gate line and the gate insulating layer;
a data line and a drain electrode on the first insulating layer, the data line including a source electrode;
a second insulating layer on the data line and the drain electrode;
a first field generating electrode on the second insulating layer;
a first contact hole in the first insulating layer and the gate insulating layer, the first contact hole exposing the source electrode;
a second contact hole in the first insulating layer and the gate insulating layer, the second contact hole exposing the drain electrode; and
further comprising
a first connection assistant member in the first contact hole, and
a second connection assistant member in the second contact hole.

24. The thin film transistor array panel of claim 23, wherein:
the first connection assistant member and the second connection assistant member include one of molybdenum (Mo), copper (Cu), aluminum (Al), nickel (Ni), platinum (Pt), gold (Au), silver (Ag) and chromium (Cr).

25. The thin film transistor array panel of claim 23, wherein:
the first connection assistant member and the second connection assistant member are respectively in the first contact hole and the second contact hole by an inkjet printing method using a laser.

26. The thin film transistor array panel of claim 23, wherein:
the first connection assistant member and the second connection assistant member are respectively in the first contact hole and the second contact hole by a paste method using a needle.

27. The thin film transistor array panel of claim 23, wherein:
the first connection assistant member and the second connection assistant member respectively in the first contact hole and the second contact hole by collecting small metallic particles.

28. The thin film transistor array panel of claim 23, wherein:
the first connection assistant member and the second connection assistant member are respectively in the first contact hole and the second contact hole by an electroless plating method.

29. The thin film transistor array panel of claim 23, wherein:
the first connection assistant member and the second connection assistant member have a multi-layered structure including a lower seed layer and an upper plating layer.

30. The thin film transistor array panel of claim 23, wherein:
the source electrode is in electrical connection with the source region through the first connection assistant member in the first contact hole.

31. The thin film transistor array panel of claim 23, wherein:
the drain electrode is in electrical connection with the drain region through the second connection assistant member in the second contact hole.
